(19) United States
(12) Patent Application Publication
(10) Pub. No.: US 2007/0138952 A1
(43) Pub. Date: Jun. 21, 2007

(54) Polymer light-emitting diode and manufacturing method thereof

(75) Inventors: Kou Chen Liu, Longtan Township (TW); Chao Wen Teng, Yuanlin Township (TW)

Correspondence Address: John S. Egbert;Egbert Law Offices, 7th Floor, 412 Main Street, Houston, TX, 77002, US

(73) Assignee: CHANG GUNG UNIVERSITY, Tao-Yuan (TW)

(21) Appl. No.: 11/313,156

(22) Filed: Dec. 20, 2005

(51) Int. Cl. H01L 51/54; H01L 51/56

(52) U.S. Cl. 313/506; 428/690; 428/917; 313/503; 313/504; 427/66

(57) ABSTRACT

A manufacturing method for a polymer light-emitting diode (PLED) is disclosed, which includes the steps of cleaning an anode layer, treating the anode layer with oxygen plasma, forming a hole transport layer (HTL) on the anode layer, forming an emitting material layer (EML) on the HTL, forming an electron injection layer (EIL) on the EML, and forming a transparent cathode layer on the EIL, wherein the transparent cathode layer is formed at a temperature below 101° C. A polymer light-emitting diode manufactured by the above method is also disclosed, which has an anode layer, an HTL disposed above the anode layer, an EML disposed above the HTL, an EIL disposed above the EML, and a transparent cathode layer that is formed at a temperature below 101° C. and is disposed above the EIL. The PLED of the present invention exhibits improved current-voltage and EL (electroluminescence)-intensity characteristics.

### RELATED U.S. APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### FIELD OF THE INVENTION

The present invention relates to a polymer light-emitting diode and a manufacturing method thereof, and more particularly, to a polymer light-emitting diode and a manufacturing method thereof with an ITO (indium tin oxide) cathode layer deposited at a temperature below 101° C.

### BACKGROUND OF THE INVENTION

In 1987, C. W. Tang developed an organic light-emitting diode (OLED) made of small molecular materials. The OLED has been attracting high interest due to its superior qualities of self-emission, wide angle of view, high response speed and portability. In 1990, Richard Friend of Cambridge University utilized polymer materials to fabricate the polymer light-emitting diode (PLED) and boosted the study of the organic light-emitting devices. Because polymer materials are soluble in solvents, diverse fabrication processes of the PLED are available, such as spin coating, ink-jet printing and roll-to-roll. Thus, the diverse fabrication processes benefit the development of large-area and flexible electronic devices. The organic light-emitting devices are classified, by material, into small molecules and polymers. The former are called OLEDs and the latter PLEDs. Also, they can be classified, by emission direction, into bottom emission, top emission and all-emission. FIGS. 1-3 show the schematic structure of the above three organic light-emitting devices, respectively. The bottom emission structure 1 comprises, from top to bottom, an opaque metal cathode 11, an electron injection layer (EIL) 12, an emitting material layer (EML) 13, a hole transport layer (HTL) 14 and a transparent anode 15. The top emission structure 2 comprises, from top to bottom, a transparent cathode 21, the EIL 12, the EML 13, the HTL 14 and an opaque anode 22. The all-emission structure 3 comprises, from top to bottom, the transparent cathode 21, the EIL 12, the EML 13, the HTL 14 and the transparent anode 15. The emissive theory of the organic light-emitting diodes is based on injections of electrons and holes, which come from the cathode (11 or 21) and the anode (15 or 22) respectively. After recombining within the EML 13, the energy is transferred into visible light. In terms of applications, the top emission structure 2 would be the better candidate for the next generation display because the emitted light is not blocked by the electrical circuit at the bottom. The transparent conductive oxide (TCO) is usually employed as the transparent cathode 21, especially ITO (Indium Tin Oxide). However, the high work function of ITO will create the high electron injection barrier. In order to improve the electron injection behavior, a thin LiF layer, as the EIL 12, is inserted between the transparent cathode 21 and the EML 13. Up to now, it has been an effective method to reduce the electron injection barrier. Unfortunately, the issue of Li (lithium) diffusion into the EML 13 degrades the performance of the organic light-emitting devices. In the top emission process, ITO is sputtered onto the LiF layer. Usually, the sputtering of ITO is performed at a higher temperature (>300° C.) to obtain lower resistivity. Nevertheless, the higher the deposition temperature of the substrate is, the worse the Li diffusion problem becomes. In addition, high deposition temperature causes damage to the EML 13. Therefore, these two contradictory problems have to be cautiously considered during the transparent ITO cathode formation.

### BRIEF SUMMARY OF THE INVENTION

The primary objective of the present invention is to provide a manufacturing method of a polymer light-emitting diode, by forming the transparent cathode at a temperature below 101° C., to improve the current-voltage and EL (electroluminescence)-intensity characteristics and to prevent the organic layer from damage.

The secondary objective of the present invention is to provide a polymer light-emitting diode with improved current-voltage and EL-intensity characteristics.

In order to achieve the objective, the present invention discloses a manufacturing method of a polymer light-emitting diode: cleaning an anode layer; treating the anode layer with oxygen plasma; forming a hole transport layer (HTL) on the anode layer; forming an emitting material layer (EML) on the HTL; forming an electron injection layer (EIL) on the EML and forming a transparent cathode layer on the EIL at a temperature below 101° C. The present invention also discloses a polymer light-emitting diode comprising: an anode layer; a hole transport layer (HTL) disposed above the anode layer; an emitting material layer (EML) disposed above the HTL; an electron injection layer (EIL) disposed above the EML, and a transparent cathode layer disposed above the EIL, wherein the transparent cathode layer is deposited at a temperature below 101° C.

### BRIEF DESCRIPTION OF THE SEVERAL VIEWS OF THE DRAWINGS

The invention will be described according to the appended drawings.

FIG. 1 shows a schematic view of a structure of a bottom-emission organic light-emitting device of the prior art.

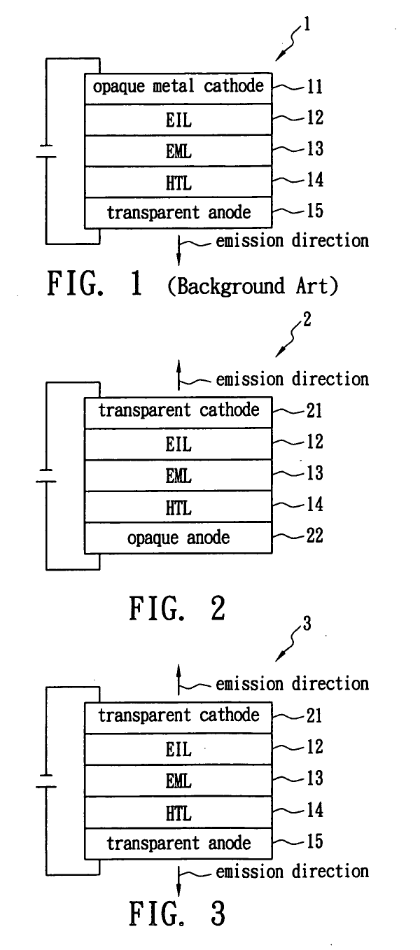

FIG. 2 shows a schematic view of a structure of a top-emission organic light-emitting device.

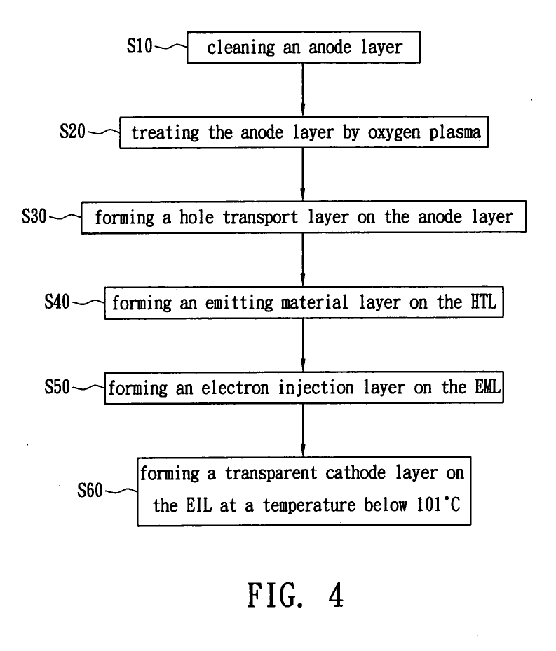

FIG. 3 shows a schematic view of a structure of an all-emission organic light-emitting device.

FIG. 4 shows a flow chart of the manufacturing method of a PLED of the present invention.

FIGS. 5-7 show graph illustrations of the current-voltage and optical characteristics of the light-emitting diode of the present invention.

FIG. 8 is another graph illustration of the depth profile of Li of the light-emitting diode of the present invention.

### DETAILED DESCRIPTION OF THE INVENTION

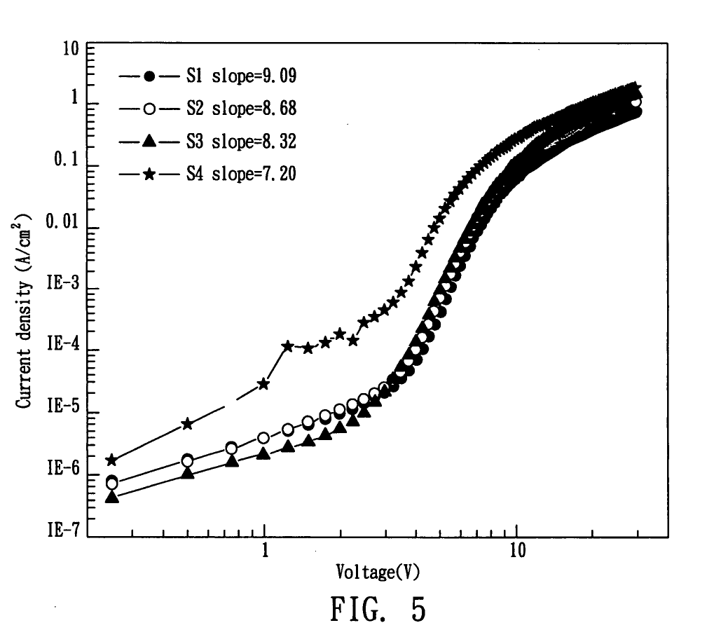

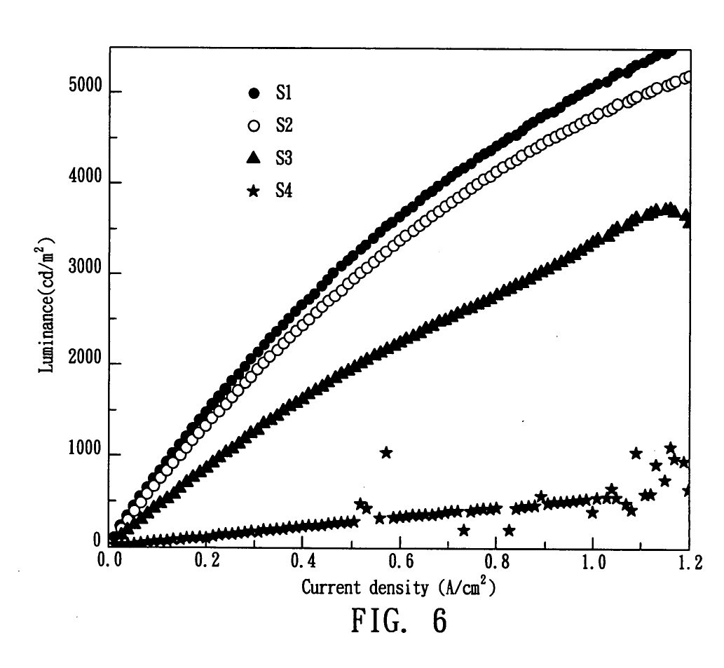

The manufacturing method of a polymer light-emitting diode of the present invention is described as follows. Referring to FIG. 4 and FIG. 3, an ITO-coated glass substrate, as an anode layer 15, is immersed in a standard wet clean (step S10). The standard wet clean is performed in a supersonic vibrator at temperature of 50° C. to 60° C. Then, the ITO-coated glass substrate is cleaned sequentially by de-ionized (DI) water, acetone, DI water, isopropyl alcohol (IPA) and DI water for 10 minutes. After that, the ITO-coated glass substrate is dried by a nitrogen gun. In the next step, the ITO-coated glass substrate is treated with oxygen plasma (step S20), in which the ITO substrate is sent to a plasma chamber for oxygen plasma treatment at 20 mTorr (20×10⁻³ Torr) with RF power of 200 Watts to remove the hydrocarbons from the surface of the ITO-coated glass substrate. To get rid of particles originating during oxygen plasma treatment, the ITO-coated glass substrate is cleaned by DI water again. Next, a 70-nm-thick HIL 14 of [poly (3, 4-ethylenedioxythiophene)-poly (4-styrene sulfonate)] (PEDOT-PSS) is deposited by a spin-coating technique (step 30). The HIL 14 is then baked in a glove box at 120° C. for 15 minutes to remove the solvent acquired during spin coating. Then, a 70-nm-thick EML 13 of polyfluorene [poly (9, 9-dioctylfluorene)](PF) is also deposited on the HIL 14 by the spin-coating technique (step 40). After-deposition of the PF layer, it is baked in the glove box at 120° C. for 30 minutes to remove the solvent. After that, a LiF film with a thickness of 1.5 nm, as the material of the EIL 12, is deposited on the EML 13 by thermal evaporation (step 50). The thickness of the LiF film can be precisely controlled due to an effusion cell, which can heat the quartz crucible uniformly. The EIL 12 functions to increase electron tunneling into the EML 13 and to lower the barrier height between the transparent cathode layer 21 and the EML 13. The barrier height is lowered because the EIL 12 reacts with the EML 13 to result in band bending between them. Then, an ITO film, as the transparent cathode layer 21, is deposited on the EIL 12 by sputtering with DC power of 50 Watts at 5 mTorr in Argon ambient (step 60). Sputtering is performed in a sputtering chamber, which is first pumped down below 7×10⁻⁶ Torr to remove the impurities inside; the chamber pressure is kept at 5 mTorr during sputtering. One feature of the sputtering chamber is that a temperature controller is equipped to control the temperature of the ITO-coated glass substrate during sputtering, which approximates to ITO deposition temperature. The low DC power (50 Watts) used in the sputtering chamber is to keep the EML 13 from being damaged by ion bombardment.

In the manufacturing method of the present invention mentioned above, the anode layer 15 is not limited to an ITO-coating glass substrate. If an opaque conductive layer such as a thin metal film is used, a top-emission PLED is formed. Due to lower ITO deposition temperature, a flexible substrate e.g., polyethylene terephthalate (PET), can be utilized to form a flexible PLED device. The material of the EIL 12 is not limited to LiF. Any material that increases electron injection into the EML 13 or lowers the barrier height between the EML 13 and the transparent cathode layer 21, for example, sodium fluoride (NaF), cesium fluoride (CsF) or sodium chloride (NaCl), can serve as the EIL 12.

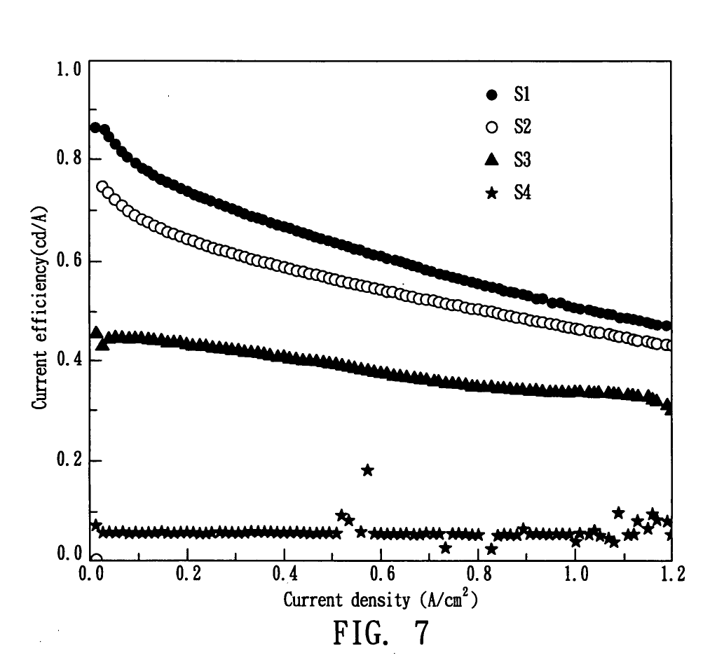

FIGS. 5-7 show the current-voltage and optical characteristics of four PLED devices (S1, S2, S3 and S4) manufactured by the method of the present invention with different ITO deposition temperatures, wherein the first three are embodiments with ITO deposition temperatures below 101° C. and only S4 experienced a LiF layer heat treatment of 100° C. All the measurements are conducted at room temperature. Table 1 shows the growth conditions for the four PLED devices after deposition of the EML 13. Basically, the LiF film as an interlayer, between the ITO film and the EML, and the ITO film are deposited with/without heat treatments after the EIL 12 is deposited.

TABLE 1
Heat treatment conditions

| | Thickness of LiF | | ITO deposition |
|---|---|---|---|
| PLED | (nm) | Heat treatment (° C.) | temperature (° C.) |
| S1 | 1.5 | — | 25 |
| S2 | 1.5 | — | 60 |
| S3 | 1.5 | — | 100 |
| S4 | 1.5 | 100 | 25 |

FIG. 5 shows the current density versus voltage (J-V) characteristics of the four PLEDs and can be explained by the trapped-charge-limited (TCL) theory (refer to “Relationship between electrominescence and current transport in organic heterojunction light-emitting devices”, J. Appl. Phys. 79(10), 15 May 1996) as below:

$${J}_{TCL} = {N}_{LUMO} {μ}_{n} {{q}^{( 1 - m ) ,} ( \frac{ɛ m}{{N}_{1} ( m + 1 )} )}^{m ,} {( \frac{2 m + 1}{m + 1} )}^{( m + 1 )} \frac{{V}^{( m + 1 )}}{{d}^{( 2 m + 1 )}}$$

, where N_{LUMO} is the density of states in the lowest unoccupied molecular orbital (LUMO) band, μn is the electron mobility, q is the electronic charge, ε is the permittivity, V is the applied voltage, d is the ETL thickness, and m=Tₜ/T and Tₜ=Eₜ/K, where Eₜ is the characteristic trap energy state of the trap, K is Boltzmann's constant and T is the ambient temperature. Therefore, the value of m from the slope of log(J) versus log(V) at the high operating voltage region can be calculated. The values of slopes are found to be 9.09, 8.68, 8.32 and 7.2 for S1, S2, S3 and S4, respectively. If the trap density is high, the value of the slope is relatively small. The high trap density can capture the free carriers, resulting in a slow rise in current. It is observed that the slope of log(J)-log(V) curve is decreased with increasing ITO deposition temperature of PLED devices. That means that the captured free carriers are increased by increasing the ITO deposition temperature (refer to S1-S3) as well as the heat treatment temperature (100° C.) of PLED devices after the LiF film deposition (refer to S4). It means that the heating process with the LiF layer will create the additional trap in the PLED devices. It indicates that the PLED devices with heat treatment can create the higher trap concentration and can block the carrier transport in organic material.

FIG. 6 shows the luminance of the four PLED devices. The S1 device, with an ITO deposition temperature of room temperature (i.e., 25° C.), exhibits a higher electroluminescence than that of the others. It shows that the heating process with the transparent anode layer and the LiF film will cause the Li diffusion in the organic layer (EML).

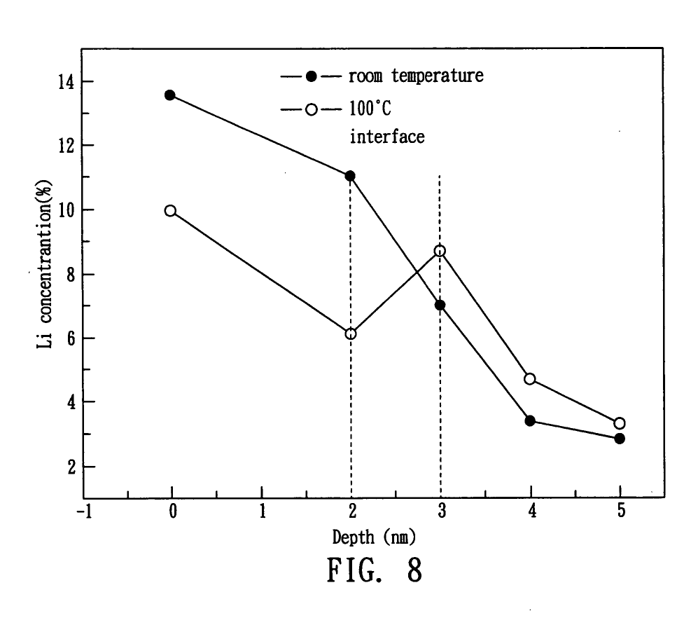

Referring to FIG. 7, it shows that the S1 device with an ITO deposition temperature of room temperature has higher current efficiency than that of the others. FIG. 8 is the depth profile of Li of a PLED device, which is studied by XPS (X-Ray Photoelectron Spectroscopy) measurement, before (i.e., at room temperature) and after a heating process of 100° C. After the heating process, the Li can be diffused into the organic layer (EML), resulting in high concentration traps. Therefore, the performance of the PLED device can be lowered due to the highest traps with high ITO deposition temperature.

The PLED and the manufacturing method thereof of the present invention, by forming the transparent cathode layer at a temperature below 101° C., achieve the objectives of preventing the organic layer of the PLED from damage and providing a PLED with improved current-voltage and EL-intensity characteristics that result from the increase of electron tunneling into the EML and lowering of the barrier height between the EIL and the transparent cathode layer.

The above-described embodiments of the present invention are intended to be illustrative only. Numerous alternative embodiments may be devised by those skilled in the art without departing from the scope of the following claims.

I claim:

1. A polymer light-emitting diode, comprising:
an anode layer;
a hole transport layer (HTL) disposed above the anode layer;
an emitting material layer (EML) disposed above the HTL;
an electron injection layer (EIL) disposed above the EML; and
a transparent cathode layer disposed above the EIL, wherein the transparent cathode layer is formed at a temperature below 101° C.

2. The polymer light-emitting diode of claim 1, wherein the EIL increases electron tunneling into the EML.

3. The polymer light-emitting diode of claim 1, wherein the EIL reacts with the EML to result in band bending.

4. The polymer light-emitting diode of claim 1, wherein the EIL is formed by thermal evaporation.

5. The polymer light-emitting diode of claim 1, wherein the EIL is comprised of material selected from the group consisting of sodium fluoride (NaF), cesium fluoride (CsF) and sodium chloride (NaCl).

6. The polymer light-emitting diode of claim 1, wherein the material of the EIL is lithium fluoride (LiF).

7. The polymer light-emitting diode of claim 1, wherein the HTL is comprised of material being [poly (3,4-ethylenedioxythiophene)-poly (4-styrene sulfonate)] (PEDOT-PSS).

8. The polymer light-emitting diode of claim 1, wherein the EML is comprised of material being polyfluorene (PF).

9. The polymer light-emitting diode of claim 1, wherein the transparent cathode layer is comprised of material being indium tin oxide (ITO).

10. The polymer light-emitting diode of claim 1, wherein the anode layer is a transparent anode layer.

11. The polymer light-emitting diode of claim 1, wherein the anode layer is comprised of material being indium tin oxide (ITO).

12. The polymer light-emitting diode of claim 1, wherein the anode layer is flexible.

13. A method for manufacturing a polymer light-emitting diode, comprising the steps of:
cleaning an anode layer;
treating the anode layer with oxygen plasma;
forming a hole transport layer (HTL) on the anode layer;
forming an emitting material layer (EML) on the HTL;
forming an electron injection layer (EIL) on the EML; and
forming a transparent cathode layer on the EIL at a temperature below 101° C.

14. The method for manufacturing a polymer light-emitting diode of claim 13, wherein the anode layer is transparent.

15. The method for manufacturing a polymer light-emitting diode of claim 13, wherein the step of forming the EIL on the EML comprises:
increasing electron tunneling into the EML.

16. The method for manufacturing a polymer light-emitting diode of claim 13, wherein the step of forming the electron injection layer on the EML comprises:
generating band bending between the EIL and the EML.

17. The method for manufacturing a polymer light-emitting diode of claim 13, wherein material of the transparent cathode layer is indium tin oxide (ITO).

18. The method for manufacturing a polymer light-emitting diode of claim 13, wherein material of the EIL is lithium fluoride (LiF).

19. The method for manufacturing a polymer light-emitting diode of claim 13, wherein the material of the EIL is selected from the group consisting of sodium fluoride (NaF), cesium fluoride (CsF) and sodium chloride (NaCl).
